(19) United States
(12) Patent Application Publication
(10) Pub. No.: US 2002/0046944 A1
(43) Pub. Date: Apr. 25, 2002

(54) Method and apparatus for reducing noise in a sputtering chamber

(76) Inventor: Ehood Geva, Palo Alto, CA (US)

Correspondence Address: PATENT COUNSEL, APPLIED MATERIALS, INC., Legal Affairs Department, P.O.BOX 450A, Santa Clara, CA, 95052, US

(21) Appl. No.: 09/893,811

(22) Filed: Jun. 27, 2001

Related U.S. Application Data
(60) Provisional application No. 60/214,817, filed on Jun. 28, 2000.

(51) Int. Cl. C23C 14/34

(52) U.S. Cl. 204/298.08; 204/192.12; 204/298.03; 204/298.11; 204/298.06

(57) ABSTRACT

A sputter deposition chamber may be fitted with measures to prevent or reduce electrical noise that might otherwise interfere with a controller for the sputter deposition chamber. A grounded shield plate may be coupled to an insulating member by which a sputtering target is mounted in the chamber. A ground line, separate from a power supply line, may be coupled to the chamber's enclosure wall and to a varying power supply. One or more filters may be coupled in series between chamber components and a controller associated with the chamber.

### CROSS REFERENCE TO RELATED APPLICATION

This application claims priority from U.S. Provisional Patent Application Serial No. 60/214,817, filed Jun. 29, 2000, which is hereby incorporated by reference herein in its entirety.

### FIELD OF THE INVENTION

The present invention relates to the sputter deposition of material layers. More particularly, the present invention relates to methods and apparatus for depositing films that apply AC (e.g., radio frequency (RF)) power to a chamber coil and/or to a substrate support, or that apply power to a sputtering target.

### BACKGROUND OF THE INVENTION

Manufacture of certain semiconductor devices requires a sputtering process in which a target is mounted in a sputtering chamber and bombarded with ions. The ion bombardment causes the target to emit molecules that are deposited on a substrate that is the subject of the sputtering process.

FIG. 1 is a schematic side elevational view of a conventional chamber 11 adapted to sputter deposit a layer of material such as aluminum nitride. The chamber 11 comprises a chamber enclosure having an enclosing wall 13, and an insulating region 15 coupled to the enclosing wall 13 and adapted to support a sputtering target 19. The chamber 11 is adapted to couple the sputtering target 19 to a source of varying power (e.g., a pulsed direct current power source that is pulsed by being repeatedly turned on and off). Specifically, a power supply line 21 couples the target 19 to a varying power source 23 as shown in FIG. 1. Conventionally the power supply line 21 may comprise a coaxial cable, a center portion of which supplies power to the target 19, and an outer shield portion of which provides a ground line between the target 19 and the varying power supply 23. The insulating region 15 prevents the varying power applied to the target 19 from being transmitted to the enclosing wall 13.

A controller C is coupled to various chamber components via a plurality of controller wires 26, and functions to control the chamber components coupled thereto.

The present inventors have discovered that power supplied from the varying power source 23 to the sputtering target 19 tends to couple to other chamber components, thereby causing undesirable effects (i.e., electrical noise). Among the possible effects of such noise are causing an erroneous high-voltage reading which may cause the controller C to terminate processing (i.e., triggering an emergency shutoff of controller C). Other undesirable effects or noise may include erroneous data readings on the monitor of the controller C, fluctuation or instability of the pointer on the monitor of controller C, etc.

Accordingly, the present inventors have recognized a need to address noise problems associated with a power source for a sputtering chamber.

### SUMMARY OF THE INVENTION

To reduce the noise experienced by conventional chambers that apply AC (e.g., RF) power to a chamber coil and/or to a substrate support, or that apply pulsed DC power to a sputtering target, the inventive chamber comprises one or more of the following features:

a grounded shield plate coupled to a sputtering target (e.g., via an insulating member);

a ground line, separate from a power supply line (i.e., other than the shield portion of the power supply line) coupled to both the chamber's enclosure wall and to a varying power supply; and/or

one or more filters coupled in series between one or more chamber components and a controller C.

In one aspect the ground line is as short as possible, and the varying power supply is installed close to the inventive chamber so as to reduce the length of the power supply line, thereby minimizing detrimental capacitance and inductance that may occur therealong. The mechanism for grounding the shield plate may comprise a metal block which couples to both the shield plate and the chamber's enclosure wall via a plurality of springs. The one or more filters may be designed to reject the specific noise bandwidth (e.g., RF noise bandwidth) detected on the specific controller wire to which the filter is coupled.

### BRIEF DESCRIPTION OF THE DRAWINGS

FIG. 1 is a schematic side elevational view of a conventional chamber 11 adapted to sputter deposit a layer of material;

FIG. 2 is a schematic side elevational view of an inventive chamber 111;

FIG. 3 is a schematic diagram of an exemplary filter 33 for filtering controller wires 401a-d in accordance with the present invention; and

FIGS. 4A and 4B are diagrammatic side views of an exemplary inventive chamber 411 configured for aluminum nitride deposition, wherein a shutter disk is shown in a closed position (FIG. 4A) and in an open position (FIG. 4B).

### DETAILED DESCRIPTION OF THE PREFERRED EMBODIMENTS

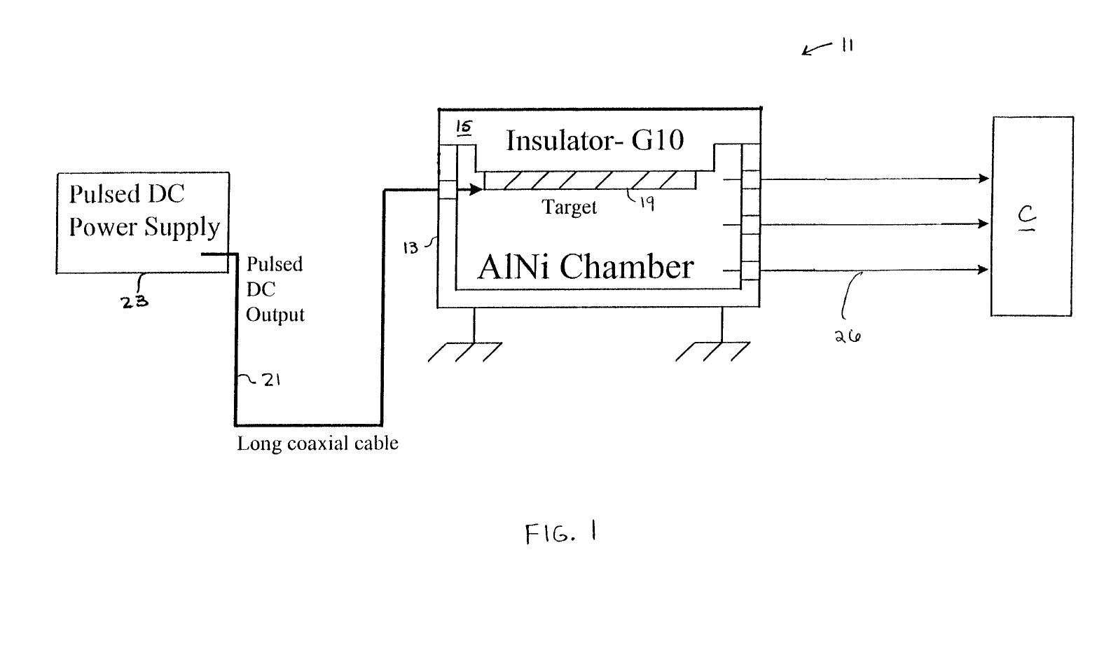

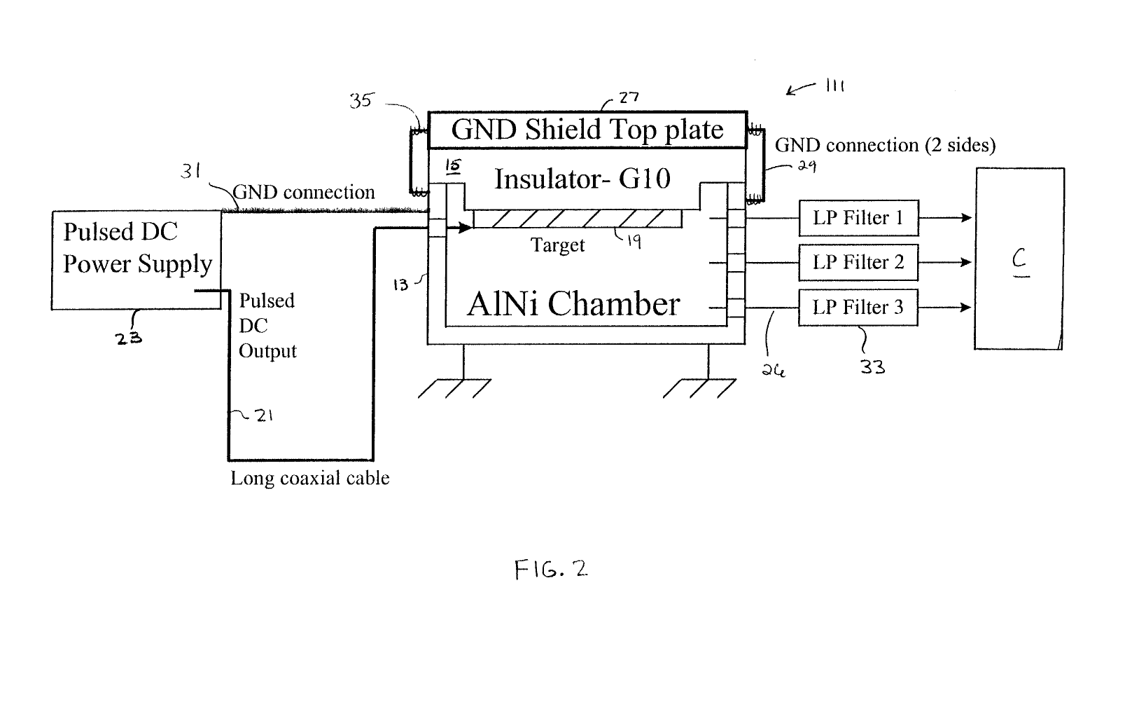

FIG. 2 is a schematic side elevational view of an inventive chamber 111. The inventive chamber 111 comprises the same components as those described with reference to the conventional chamber 11 of FIG. 1. Accordingly, the components which are the same will be briefly enumerated, and only the aspects of the inventive chamber 111 that differ from the conventional chamber 11 will be described in detail.

Briefly, the chamber 11 includes a chamber enclosure having an enclosing wall 13 and an insulating region 15 adapted to support a sputtering target 19. A power supply line 21 couples the target 19 to a varying power source 23. A controller C is coupled to various chamber components via a plurality of controller wires 26.

To reduce the noise experienced by the conventional chamber 11, the inventive chamber 111 comprises one or more of the following features:

a shield plate 27 coupled to the insulating region 15, and a grounding mechanism 29 coupled to the shield plate 27 and to the enclosing wall 13 so as to provide electrical grounding therebetween;

a ground line 31, separate from the power supply line 21 (i.e., other than the shield portion of the power supply line 21) coupled to both the enclosing wall 13 and to the varying power supply 23; and/or

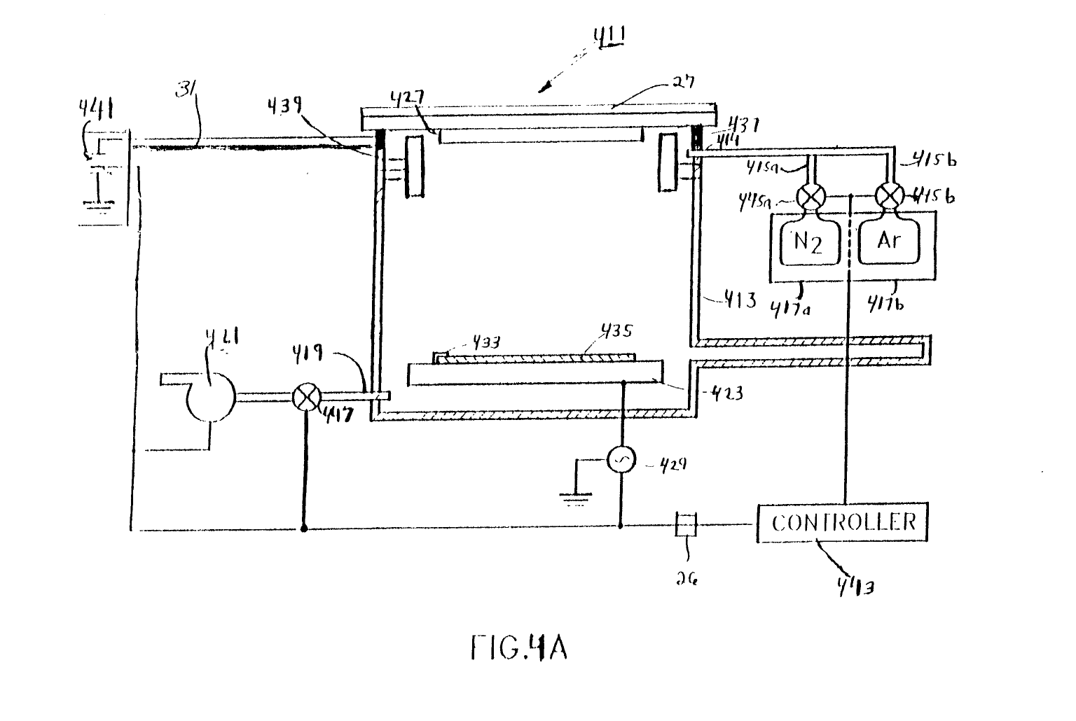

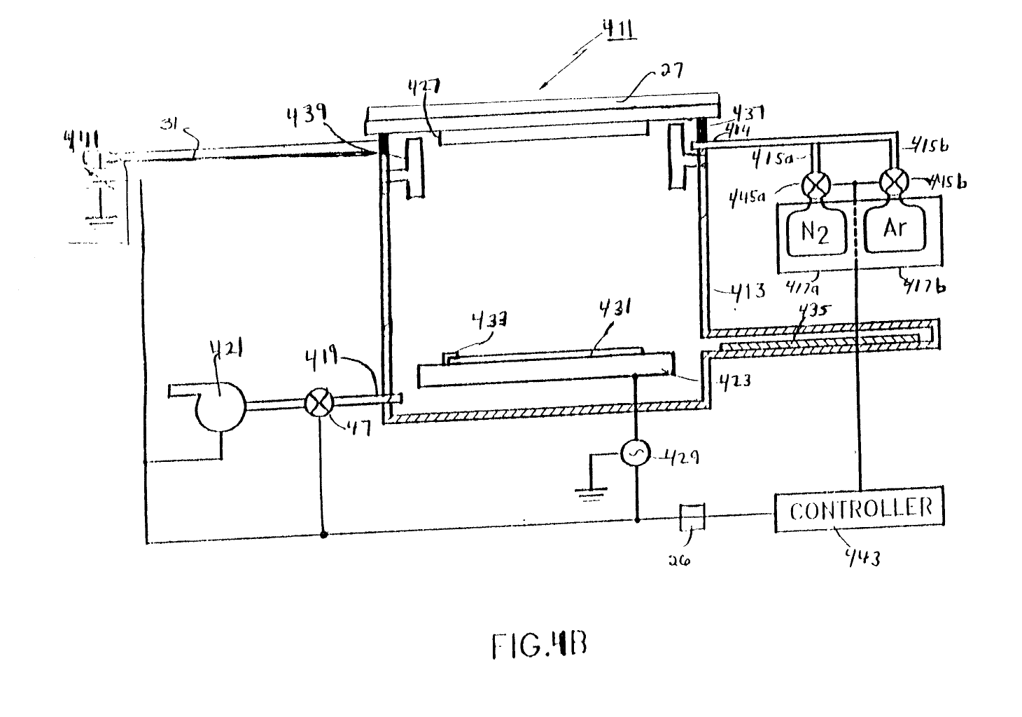

one or more filters 33 coupled to controller wires 26 in series between the one or more chamber components (see FIG. 4), and the controller C.

In one aspect the ground line 31 is as short as possible, and the varying power supply 23 is installed close to the inventive chamber 111 so as to reduce the length of the power supply line 21, thereby minimizing detrimental capacitance and inductance that may occur therealong. The grounding mechanism 29 may comprise a metal block which couples to both the shield plate 27 and the enclosure wall 13 via a plurality of springs 35. The one or more filters 33 may be designed to reject the specific noise bandwidth detected on the specific controller wire 26 to which the filter 33 is coupled. The filters 33 may be designed using a simulation tool in order to obtain a desired frequency response, and may be designed for differential mode filtering or for single mode filtering, as is known in the art.

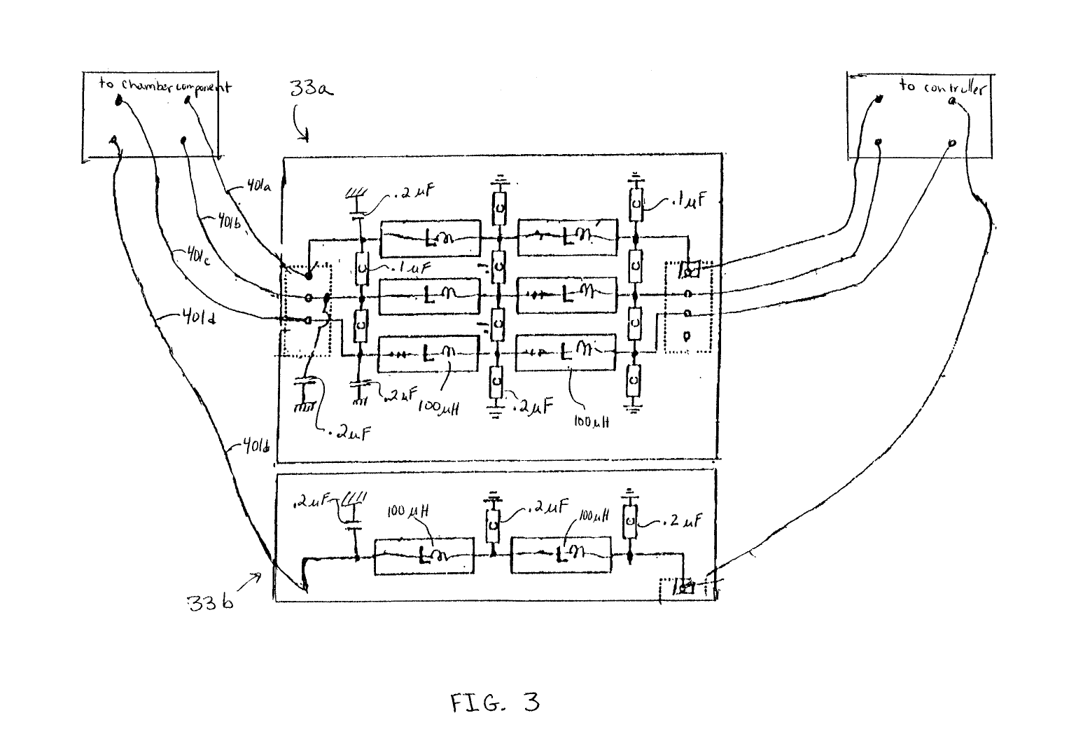

FIG. 3 is a schematic diagram of an exemplary filter 33 for filtering controller wires 401a-d in accordance with the present invention. With reference to FIG. 3, the filter 33 comprises channel circuitry 33a and 33b for filtering controller wires 401a-d (e.g., a differential mode filter circuit comprising a plurality of capacitors and inductors configured as shown in FIG. 3). The specific capacitor and inductor values shown in FIG. 3 (e.g., 0.2 microFarad capacitors coupled between each controller wire 401a-d and ground, 0.1 microFarad capacitors coupled between the controller wires 401a-c, and 100 microHenry inductors coupled in series with each controller wire 401a-d) are selected to provide low-pass filtering for each controller wire 401a-d with a cutoff frequency of about 50 kHz (e.g., so as to reject the 70 kHz or greater pulsed D.C. signal typically applied to a target during sputter deposition of dielectric layers such as aluminum nitride.)

FIGS. 4A and 4B are diagrammatic side views of an exemplary inventive chamber 411 configured for aluminum nitride deposition, wherein a shutter disk is shown in a closed position (FIG. 4A) and in an open position (FIG. 4B). With reference to FIGS. 4A and 4B, the deposition chamber 411 generally includes a chamber enclosure wall 413 having an inlet 414 coupled to first and second gas lines 415a-b. The first and second gas lines 415a-b are coupled to a processing gas source 417a (e.g., nitrogen) and to a carrier gas source 417b (e.g., argon), respectively, and an exhaust outlet 419 is coupled to an exhaust pump 421. A substrate support 423 is disposed in the lower portion of the deposition chamber 411, and a target 427 (e.g., an aluminum target for aluminum nitride deposition or a titanium target for titanium nitride deposition) is mounted to an upper surface of the deposition chamber 411. An AC power supply 429 is operatively coupled to the substrate support 423 so that an AC power signal emitted from the AC power supply 429 will couple through the substrate support 423 to a substrate 431 (FIG. 4B) positioned thereon.

A clamp ring 433 is operatively coupled to the substrate support 423 so as to press the substrate 431 (FIG. 4B) uniformly against the substrate support 423. A shutter assembly (not shown) is rotatably mounted within the deposition chamber 411 which selectively positions a shutter disk 435 between the target 427 and the substrate support 423 (i.e., placing the shutter disk 435 in a closed position) as shown in FIG. 4A. Thus, when the shutter disk 435 is in the closed position, deposition material is prevented from depositing on surfaces below the shutter disk 435. Preferably the shutter disk 435 is positioned between the clamp ring 433 and the substrate support 423 when the shutter disk 435 is in the closed position (as shown in FIG. 4A).

The target 427 is electrically isolated from the chamber enclosure wall 413 by an insulation region 437. Any sputtered particles, which accumulate on the insulation member 437 during deposition (described below), may cause an electrical short circuit between the chamber enclosure wall 413 and the target 427 (e.g., preventing the deposition chamber 411 from functioning). Therefore, a process kit part (e.g., a shield 439) may be positioned between the target 427 and the insulation region 437 to prevent sputtered particles from accumulating on the insulation region 437.

The chamber enclosure wall 413 is preferably grounded so that a negative voltage potential may be selectively generated (e.g., pulsed ON or OFF) between the target 427 and the grounded enclosure wall 413 via a DC power supply 441. A controller 443 is operatively coupled to the DC power supply 441, to the gas lines 415a, 415b via first and second flow controllers 445a, 445b (e.g., first and second mass flow controllers) to the exhaust outlet 419 via a throttle valve 447 and to the AC power supply 429. The controller may be programmed to pulse the DC power applied to the target at a radio frequency.

In operation, to deposit either aluminum nitride or titanium nitride within the deposition chamber 411, nitrogen (e.g., a processing gas) and a carrier gas (typically a non-reactive species such as Argon) are supplied by the processing gas source 417a and by the carrier gas source 417b, and are flowed into the deposition chamber 411 through the gas lines 415a-b, respectively, and through the inlet 414 at flow rates regulated by the controller 443. The nitrogen flow rate is selected so that the nitrogen reacts with the target material forming a nitride layer (e.g., an aluminum nitride layer for an aluminum target or a titanium nitride layer for a titanium target) thereon. The controller 443 also regulates the pressure of the deposition chamber by throttling the rate at which gas is pumped through the exhaust outlet 419 (e.g., via the throttle valve 447). Accordingly, although a constant chamber pressure is maintained during deposition, a continuous supply of fresh processing gas is supplied to the deposition chamber 411.

The D.C. power supply 441 (e.g., via a command from the controller 443) applies a negative voltage to the target 427 with respect to the chamber enclosure wall 413 so as to excite the processing gas/carrier gas within the chamber 411 into a plasma state (e.g., thereby generating a plasma within the chamber 411). Ions from the plasma (e.g., argon ions) bombard the target 427, causing molecules of the nitrided target layer to sputter therefrom. The sputtered molecules travel along linear trajectories from the target 427 and deposit on the substrate 431 (FIG. 4B). The negative voltage applied to the target is turned ON and OFF at a radio frequency rate (e.g., about 70 kHZ), causing the target to be sputtered during power ON state, and allowing a fresh layer of aluminum nitride to form on the target during the power OFF state.

The use of the grounded shield plate 27, the ground line 31, and/or the one or more filters 33, significantly reduce or eliminate the occurrence of noise in the inventive deposition chamber 411. Specifically, with use of the inventive chamber, less current couples to chamber components, a higher percentage of the current is returned to the power supply (e.g., via the ground line, and via the grounded shield), and any remaining current may be filtered from the controller lines.

The foregoing description discloses only the preferred embodiments of the invention; modifications of the above disclosed apparatus and method which fall within the scope of the invention will be readily apparent to those of ordinary skill in the art. For instance, the invention is not limited to sputtering targets mounted on the top of a chamber; other mounting positions may be employed. Similarly, the AC power of frequencies other than radio frequency and the DC power pulsed at frequencies other than radio frequency may be applied to the target. Filters other than the exemplary circuits described herein may be employed, and any mechanism may be employed to ground the shield plate to the enclosure wall. The present invention also may be used within chambers that employ a coil (e.g., a high density plasma chamber) and/or an RF substrate support bias. For example, to deposit TiN or TaN, a chamber coil typically is employed within a sputtering chamber, the chamber coil is biased via a 2 MHz RF power signal and a substrate support within the chamber is biased with a 13.5 MHz RF signal. The present invention may be employed to reduce noise due to either RF power signal (e.g., by connecting the ground connection of any RF power supplies that are employed to the chamber enclosure wall of the chamber in a manner similar to the ground connection of the pulsed D.C. power supply 23 of FIG. 2).

Accordingly, while the present invention has been disclosed in connection with the preferred embodiments thereof, it should be understood that other embodiments may fall within the spirit and scope of the invention, as defined by the following claims.

The invention claimed is:

1. A chamber adapted to sputter deposit a layer of material on a substrate, comprising:
a chamber enclosure comprising:
at least one enclosing wall; and
an insulating region coupled to the enclosing wall and adapted to support a sputtering target; and
a shield plate located external to the chamber enclosure and coupled to the insulating region so that the shield plate is insulated from the sputtering target by the insulating region.

2. The apparatus of claim 1 further comprising:
a source of varying power;
a power supply line coupled to the source of varying power and to the chamber; and
a ground line, separate from the power supply line, coupled to the shield plate and to the source of varying power.

3. The apparatus of claim 1 further comprising a grounding mechanism coupled to the shield plate and to the enclosing wall.

4. The apparatus of claim 3, wherein the grounding mechanism includes a metal block coupled to the shield plate and to the enclosing wall.

5. The apparatus of claim 4, wherein the grounding mechanism further includes a plurality of springs positioned to couple the metal block to the shield plate and to the enclosure.

6. The apparatus of claim 1 further comprising:
a wire coupled to the chamber;
a controller coupled to the chamber via the wire; and
a filter coupled to the wire and coupled in series between the chamber and the controller.

7. An apparatus adapted to process a substrate, comprising:
a chamber enclosure including at least one enclosing wall;
a first component mounted inside the chamber enclosure and adapted to be selectively energized;
a source of varying power;
a power supply line coupled to the source of varying power and to the first component; and
a ground line, separate from the power supply line, coupled to the chamber enclosure and to the source of varying power.

8. The apparatus of claim 7, wherein the first component is a sputtering target.

9. The apparatus of claim 7, wherein the first component is a chamber coil.

10. The apparatus of claim 7, wherein the first component is a substrate support.

11. An apparatus adapted to process a substrate, comprising:
a chamber in which the substrate is processed;
a controller;
at least one component associated with the chamber and adapted to be controlled by the controller; and
at least one filter coupled in series between the controller and the at least one component.

12. The apparatus of claim 11, wherein the at least one filter provides differential mode filtering.

13. The apparatus of claim 11, wherein the at least one filter provides single mode filtering.

14. The apparatus according to claim 11, wherein the chamber is adapted to perform sputter deposition on the substrate.

15. A method comprising:
providing a chamber adapted to sputter deposit a layer of material on a substrate, the chamber including:
a chamber enclosure comprising:
at least one enclosing wall; and
an insulating region coupled to the enclosing wall and adapted to support a sputtering target; and
coupling a shield plate external to the chamber enclosure and to the insulating region so that the shield plate is insulated from the sputtering target by the insulating region.

16. The method of claim 15 further comprising sputtering a material layer on a substrate with the chamber.

17. A method comprising:
providing a chamber adapted to process a substrate, the chamber including:
a chamber enclosure including at least one enclosing wall; and
a first component mounted inside the chamber enclosure and adapted to be selectively energized;
coupling a source of varying power to the first component via a power supply line; and
coupling a ground line, separate from the power supply line, to the chamber enclosure and to the source of varying power.

18. The method of claim 17 further comprising sputtering a material layer on a substrate with the chamber.

19. A method comprising:
providing an apparatus adapted to process a substrate, the apparatus including:
a chamber in which the substrate is processed;
a controller; and
at least one component associated with the chamber and adapted to be controlled by the controller;
coupling at least one filter in series between the controller and the at least one component.

20. The method of claim 19 further comprising sputtering a material layer on a substrate with the chamber.
